(19) United States
(12) Patent Application Publication
(10) Pub. No.: US 2007/0170476 A1
(43) Pub. Date: Jul. 26, 2007

(54) Lateral photodetectors with transparent electrodes

(76) Inventors: Wojciech P. Giziewicz, Cambridge, MA (US); Lionel C. Kimerling, Concord, MA (US); Dong Pan, Andover, MA (US); Jurgen Michel, Arlington, MA (US); Edward H. Sargent, Toronto (CA)

Correspondence Address: GAUTHIER & CONNORS, LLP, 225 FRANKLIN STREET, SUITE 2300, BOSTON, MA, 02110, US

(21) Appl. No.: 11/336,012

(22) Filed: Jan. 20, 2006

(51) Int. Cl. H01L 31/113

(52) U.S. Cl. 257/292

(57) ABSTRACT

A photodetector includes a substrate and a layer of Ge formed on the substrate. A plurality of n-type doped regions and a plurality of p-type doped regions are formed in Ge region. These doped regions formed an alternating pattern. Electrodes are formed on n-type doped regions and on the p-type doped regions. The utilization of transparent electrodes increases the sensitivity of the photodetector without impacting speed.

### FIELD OF THE PRESENT INVENTION

The present invention relates generally to a photodetector capable of high-speed operation that may be fabricated in an integrated circuit VLSI process. More particularly, the present invention is directed to a photodetector capable of high-speed and high-sensitivity operation that is made of germanium grown on silicon. Moreover, the photodetector has a large diameter for applications using large-core optical fibers, such as polymer optical fiber.

### BACKGROUND OF THE PRESENT INVENTION

High speed silicon photodetectors are often designed with a lateral structure, rather than a vertical structure. These lateral structures typically take the form of either a PIN detector with diffused or implanted fingers or a metal-semiconductor-metal detector. As example of a conventional high speed silicon photodetector is illustrated in FIGS. 1 and 2.

As illustrated in FIG. 1, a photodetector is fabricated in a p-type substrate 5. Strips of alternating n-type (40) and p-type (50) implants are patterned. Metal electrodes 60 are deposited over these implanted regions (40 and 50). Carriers that are generated by incoming photons then drift and/or diffuse laterally, and are collected at the electrodes 60.

As illustrated in FIG. 2, a photodetector is fabricated in a lightly p-type doped region 20 created by implant or epitaxial growth. The lightly p-type doped region 20 is created on top of a substrate that is a lightly n-type doped region 10. The lightly n-type doped region 10 may also be an implant region, for example in the case of a double-well silicon CMOS process. Within the lightly p-type doped region 20, strips of alternating n-type (40) and p-type (50) implants are patterned. Metal electrodes 60 are deposited over these implanted regions (40 and 50). Carriers that are generated by incoming photons then drift or diffuse laterally, and are collected at the electrodes 60.

As further illustrated in FIG. 2, a barrier region 30 is formed to block slow carriers without degrading other properties of the photodetector. In this example, the barrier region 30 is a depletion region. It is noted that there are various other types of barrier regions that are capable of blocking the slow carriers without degrading other properties of the photodetector.

As noted above, the barrier region 30 of the photodetector blocks diffusion of carriers generated deep in the substrate, a performance limiter of silicon photodetectors. However, the conventional photodetector of FIG. 2, not withstanding its capability of blocking the slow carriers without degrading other properties of the photodetector, fails to provide appropriate sensitivity. More specifically, the metal electrodes 60 over the n-type (40) and p-type (50) implanted regions block incoming light, thereby decreasing the sensitivity of the photodetector since a large proportion of the photodetector area is covered by metal electrodes.

It is desirable to provide a photodetector that does not collect a substantial amount of the slow carriers without degrading other properties of the photodetector, and also while having an increased sensitivity. Therefore, it is desirable to use a material that has higher mobility and that absorbs light more efficiently (i.e. has a shorter absorption length) than silicon at wavelengths of interest. Additionally, it is desirable that the photodetector be compatible with silicon CMOS manufacturing processes (i.e. unlike GaAs or Ge MSM photodetectors) in order to minimize production costs.

### SUMMARY OF THE PRESENT INVENTION

One aspect of the present invention is a photodetector. The photodetector includes a substrate, the substrate being a semiconductor material; an active region formed directly on the substrate, the active region being germanium; a plurality of n-type doped regions formed in the active region; a plurality of p-type doped regions formed in the active region; a plurality of electrodes formed on the n-type doped regions formed in the active region; and a plurality of electrodes formed on the p-type doped regions formed in the active region.

Another aspect of the present invention is a photodetector. The photodetector includes a substrate, the substrate being a semiconductor material; an active region formed directly on the substrate, the active region being germanium; a plurality of n-type doped regions formed in the active region; a plurality of p-type doped regions formed in the active region; a plurality of transparent electrodes formed on the n-type doped regions formed in the active region; and a plurality of transparent electrodes formed on the p-type doped regions formed in the active region. By utilizing transparent electrodes, the amount of generated carriers is increased, thereby increasing the sensitivity of the photodetector.

A further aspect of the present invention is the above photodetector using polysilicon as the transparent electrode material. Moreover, it is noted that polysilicon makes a good electrical contact to Ge that utilizes more standard processing steps/materials than direct metal contacts to Ge. However, polysilicon electrodes may have a higher parasitic resistance than the metal, so the polysilicon electrodes may be partly or completely covered by an additional electrically conductive material.

Another aspect of the present invention is the above photodetector using a Si substrate, which is typically less expensive compared with other substrate materials such as GaAs or SOI.

### BRIEF DESCRIPTION OF THE DRAWINGS

The present invention may take form in various components and arrangements of components, and in various steps and arrangements of steps. The drawings are only for purposes of illustrating a preferred embodiment and are not to be construed as limiting the present invention, wherein:

FIG. 1 illustrates a conventional photodetector;

FIG. 2 illustrates a conventional photodetector;

FIG. 3 illustrates a photodetector according to one embodiment of the present invention;

FIG. 4 illustrates a photodetector according to another embodiment of the present invention;

FIG. 5 illustrates a photodetector according to another embodiment of the present invention; and

FIGS. 6-13 illustrate a process forming a photodetector according to another embodiment of the present invention; and

FIG. 14 illustrates a conceptual top view of a photodetector according to an embodiment of the present invention.

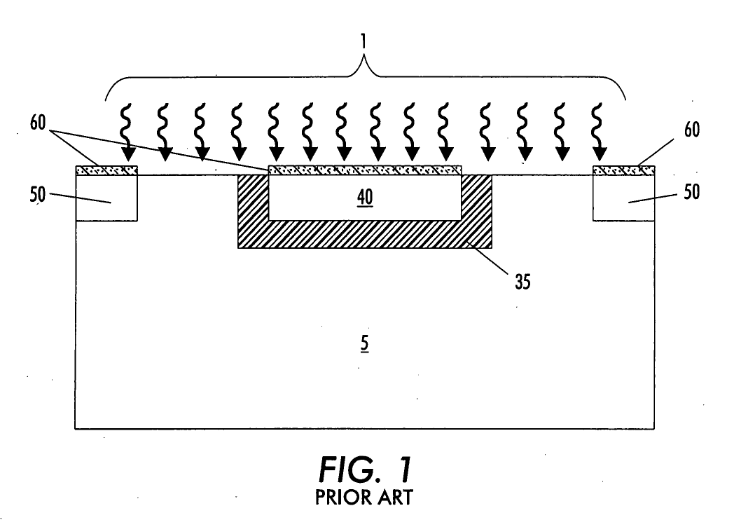

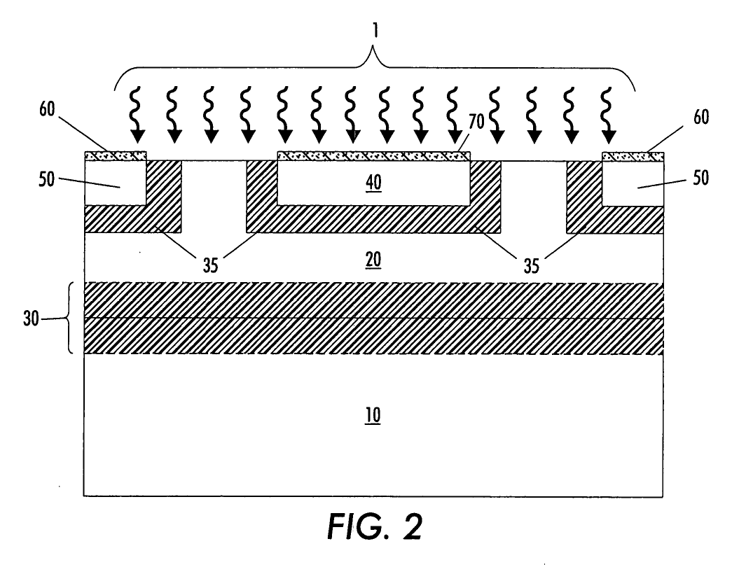

### DESCRIPTION OF THE PRESENT INVENTION

For a general understanding, reference is made to the drawings. In the drawings, like references have been used throughout to designate identical or equivalent elements. It is also noted that the drawings may not have been drawn to scale and that certain regions may have been purposely drawn disproportionately so that the features and concepts could be properly illustrated.

As noted above, it is desirable to provide a photodetector that does not collect a substantial amount of slow carriers without degrading other properties of the photodetector. The photodetector includes a substrate, the substrate being a semiconductor material; an active region formed directly on the substrate, the active region being germanium; a plurality of n-type doped regions formed in the active region; a plurality of p-type doped regions formed in the active region; a plurality of electrodes formed on the n-type and p-type doped regions formed in the active region.

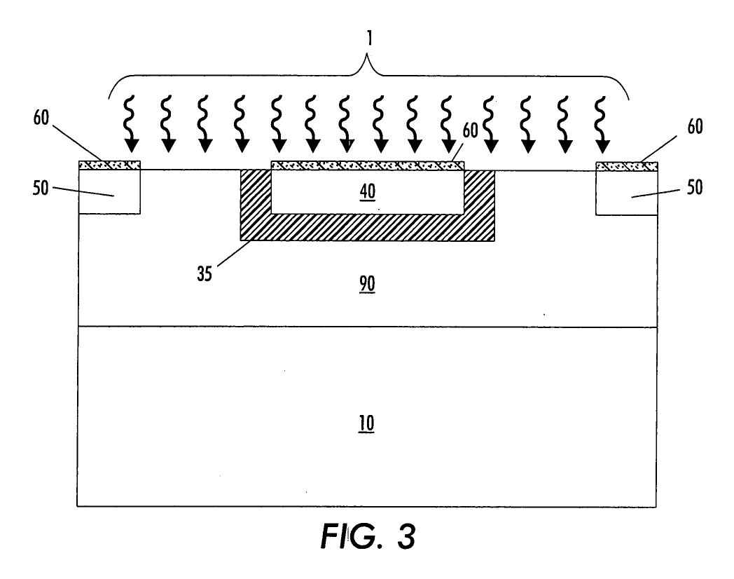

As illustrated in FIG. 3, a photodetector is fabricated in a nominally undoped Ge region 90 created by epitaxial growth on a lightly n-type semiconductor substrate 10. The lightly n-type doped region 10 may also be an implant region, for example in the case of a double-well silicon CMOS process. Within the Ge region 90, strips of alternating n-type (40) and p-type (50)) fingers are patterned. The n-type (40) fingers are surrounded by depletion regions 35 as the nominally undoped Ge 90 is generally lightly p-type due to point defects in the material. Metal electrodes 60 are deposited over fingers.

As noted above, it is desirable to provide a photodetector that does not collect a substantial amount of slow carriers without degrading other properties of the photodetector and utilizes transparent electrodes to increase the generation of carriers, thereby increasing the sensitivity of the photodetector.

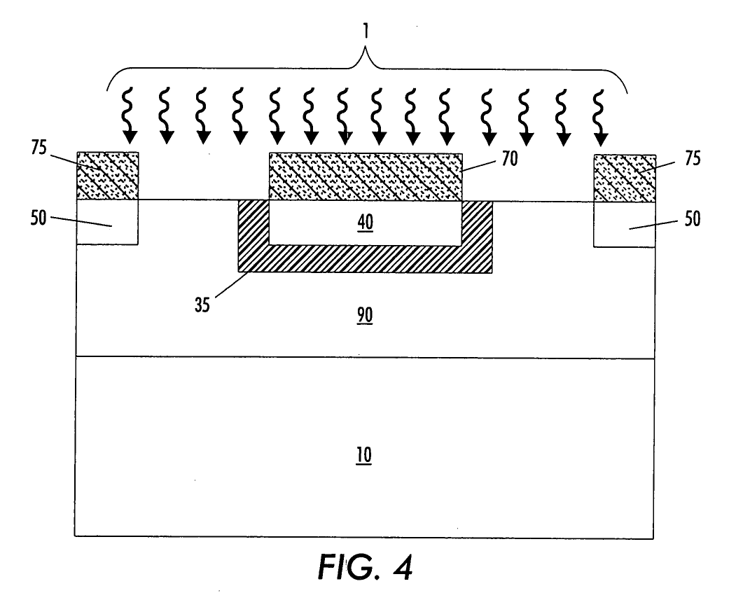

As illustrated in FIG. 4, a photodetector is fabricated in a nominally undoped Ge region 90 created by epitaxial growth on a lightly n-type semiconductor substrate 10. The lightly n-type doped region 10 may also be an implant region, for example in the case of a double-well silicon CMOS process. Within the Ge region 90, strips of alternating n-type (40) and p-type (50)) fingers are patterned. The n-type (40) fingers are surrounded by depletion regions 35 as the nominally undoped Ge 90 is generally lightly p-type due to point defects in the material.

Each n-type and p-type implanted region or finger 40 or 50 respectively has deposited thereon transparent electrode 70 or 75 respectively. In a preferred embodiment, the transparent electrode 70 comprises n-type doped polycrystalline silicon and the transparent electrode 75 comprises p-type doped polycrystalline silicon. It is further noted that the transparent electrodes 70 and 75 may comprise a different transparent conducting electrode material, such as indium tin oxide, indium zinc oxide, or zinc oxide for example.

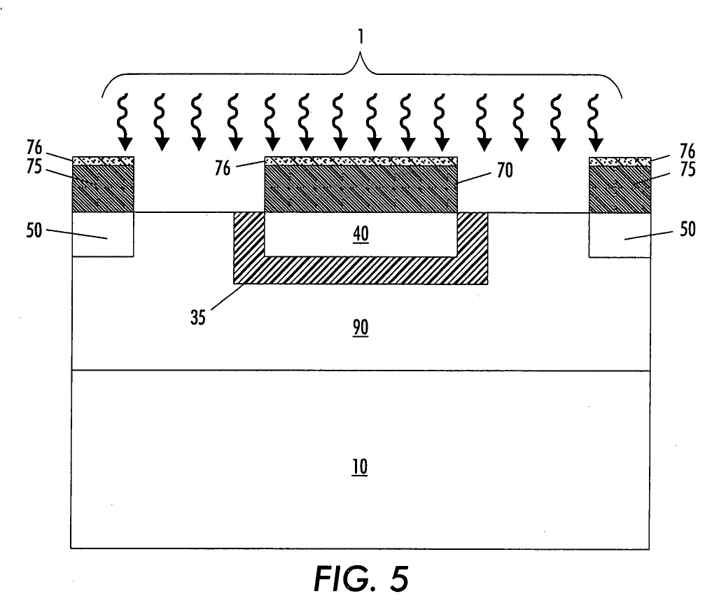

As illustrated in FIG. 5, it is noted that the electrodes 70 and 75 could be partially or completely covered by a non-transparent metal layer 76. Additionally, though polysilicon electrodes make a good electrical contact to the Ge active region, polysilicon electrodes have a higher parasitic resistance than metal electrodes. Additional metal lines over the contacts 70 and 75 are therefore desirable from the point of view of reducing the device RC time constant.

Carriers that are generated by incoming photons drift or diffuse laterally and are collected at the electrodes 60, 70 and 75. As further illustrated in FIGS. 3, 4, and 5, the Ge active region is sufficiently thick so as to absorb most of the incoming light before it passes into the substrate where it would normally generate slowly diffusing carriers. Other properties of the photodetector are not degraded by the high absorption coefficient of Ge. The absorption length of Ge is less than 0.4 μm for 850 nm light. Therefore, in the case of an application using 850 nm light, the Ge active region desired thickness is more than 0.4 μm.

By utilizing a transparent electrode, carriers are generated in the region under the electrode, increasing the sensitivity of the photodetector. The region under the n-type region 40 is also in a depleted state under normal operation, such that carrier transport would be fast. Therefore, the photodetector's sensitivity increases without affecting the speed.

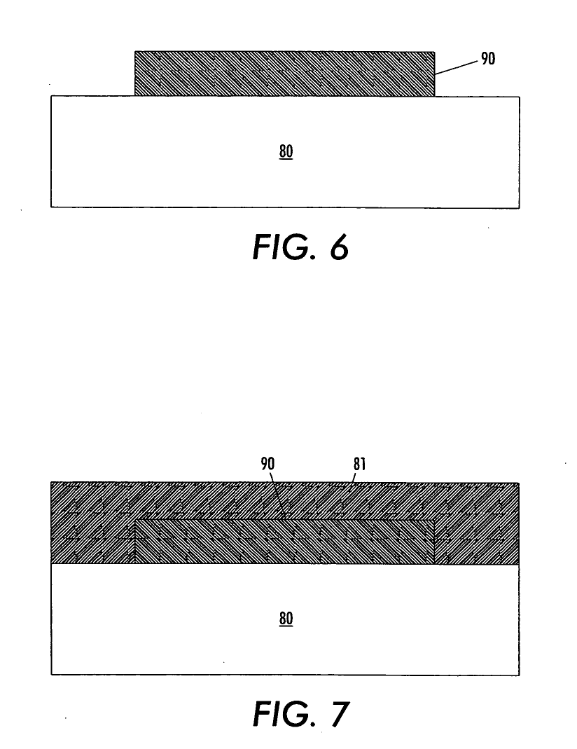

FIGS. 6-13 illustrate a typical fabrication flow of the photodetectors according to an embodiment of the invention. FIG. 6 illustrates an initial step in forming a germanium (Ge) lateral p-i-n photodetector. As illustrated in FIG. 6, a layer of germanium 90 is initially grown and annealed upon a substrate of [100] silicon 80. A pattern is created on the germanium 90 for etching such that the germanium 90 is etched to an appropriate size and position.

The Ge layer could also be grown by selective deposition using a silicon dioxide template. The Ge is deposited in a two-step CVD process comprising a thin layer grown at low temperature and a thicker layer grown at higher temperature. The Ge growth methods could include UHV-CVD and LP-CVD using a two-step method.

For UHV-CVD growth, in the first growth Ge is grown at a temperature of about 360° C. and a flow rate of about 20 sccm of GeH₄ (15% in Ar) for about 4.5 hours. The typical Ge thickness of the first growth step is about 50^{˜}100 nm. For the second step, the furnace temperature is raised to about 700° C. (between 650° C. and 750° C.). The Ge layer growth is continued at 700° C. (between 650° C. and 750° C.) under the same 20 sccm of GeH₄ (15% in Ar) for about 4-6 hours. Thermal annealing is performed at about 850° C. (between 800° C. and 900° C.) for about 30 minutes. Rapid thermal annealing could be used, as could cyclic thermal annealing. The total Ge layer thickness is between 0.4 and 1 μm. This thickness is well-suited to applications using 850 nm light, where the 1/e absorption length of 850 nm light in Ge is approximately 0.3 μm.

This is different than most published reports of vertical Ge photodetectors whose thicknesses exceed 1 μm and are targeted for 1.55 μm light operation. The Ge layer 90 is etched to an appropriate size, specifically into mesas with area above 2000 μm² which is well-suited to applications using glass or polymer optical fibers with core diameters of 62.5 μm or higher.

In FIG. 7, a layer of SiO₂ or SiON (low nitrogen concentration 0^{˜}30% for good surface passivation) 81 is deposited upon the germanium 90 via LTO or PECVD deposition. Before deposition, a short Ge etch could be performed to remove material that may have accumulated doping species from the substrate during the annealing process (i.e. fast dopant diffusion through dislocations from the substrate to the surface).

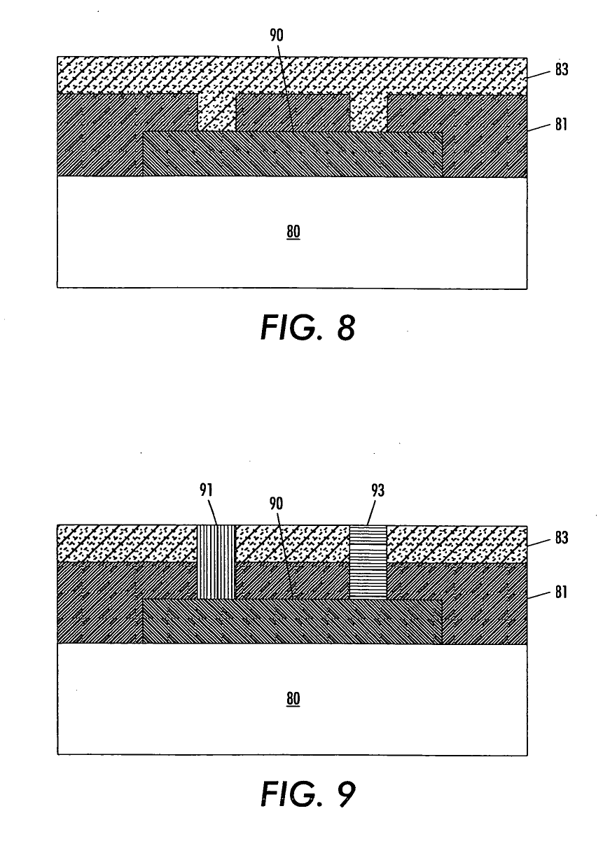

As illustrated in FIG. 8, a contact window pattern is initially etched into the layer 81 and thereafter a layer of polysilicon 83 is deposited on the layer of SiO₂ 81.

As illustrated in FIG. 9, n-type and p-type ion implantation is performed in a patterned manner into the polysilicon 83 and underlying Ge 90 layers. Ion implantation could also proceed in two steps: initial implants into Ge, polysilicon deposition, further implants into the polysilicon.

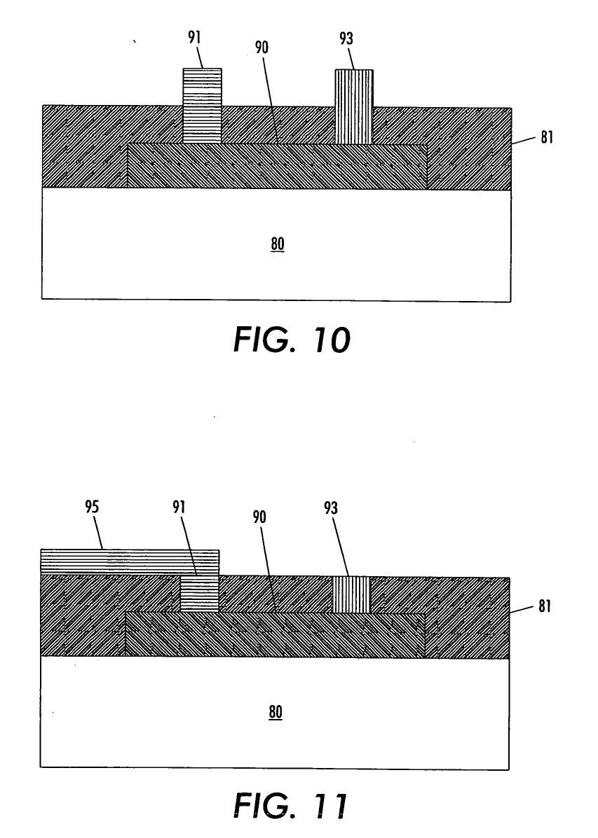

In FIG. 10, the polysilicon 83 is etched away, and in FIG. 11, a metal layer 95 is formed on the polysilicon and SiO₂ 81 layers and appropriately etched. The metal 95 is annealed to bring the metal 95 into ohmic contact with the doped material 91 and/or 93.

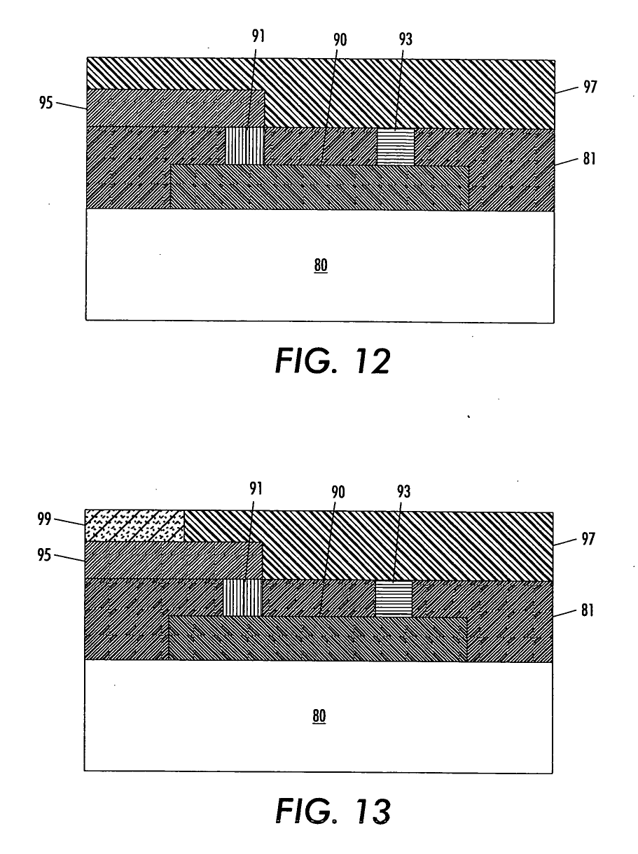

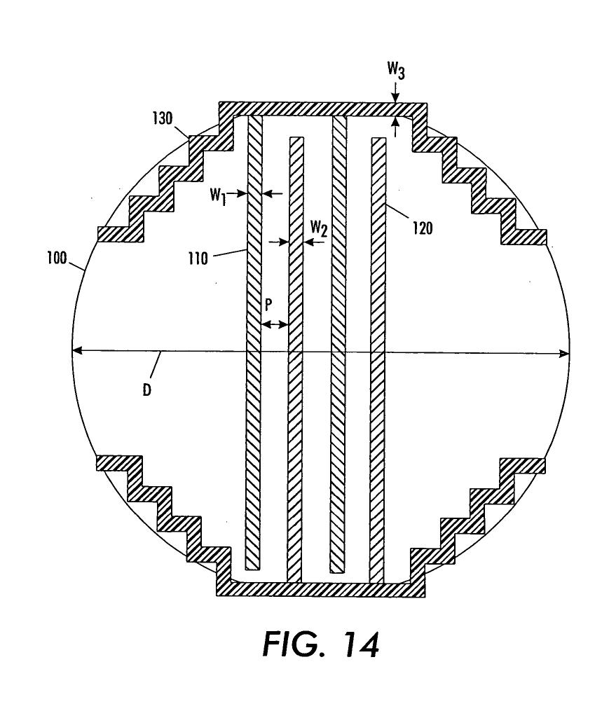

In FIG. 12, a layer of SiO₂ 97 is deposited, to form a passivation layer, upon the metal 95, and p-type doped material 93, and layer of SiO₂ 81 via PECVD oxide deposition. In FIG. 13, the layer of SiO₂ 97 is etched, and a metal 99 is deposited in the etched area. Metal 99 represents either external contact pads or a metal interconnect layer in a CMOS process, used to connect the detector contacts to other device/circuits fabricated in a standard process on the same substrate (e.g. SRAM, digital logic, transimpedance amplifiers). FIG. 14 illustrates a photodetector. More specifically, FIG. 14 illustrates a photodetector with a substrate. The substrate may be a semiconductor material. The substrate also has formed thereon, an active region 100. The active region 100 may be germanium. A plurality of n-type doped regions 120 and a plurality of p-type doped regions 110 are formed in the active region 100. The active region 100 may also include additional electrodes 125. The additional electrodes 125 may comprise aluminum or copper. The plurality of n-type doped regions 120 and the plurality of p-type doped regions 110 form an alternating pattern.

It is noted that the widths (W₁ and W₂) of the n-type doped regions 120 and the plurality of p-type doped regions 110 may be between 0.5 μm to 1 μm. Moreover, it is noted that the distance P between n-type doped trace and a p-type doped trace may be between 1 μm to 4 μm. Furthermore, it is noted that the width W₃ of the additional electrodes 125 may be between 1 μm to 2 μm. Lastly, it is noted that the diameter D of the active region 100 may be 50 μm to 400 μm.

In summary, a photodetector includes a substrate; an active region formed directly on the substrate; a plurality of n-type regions and a plurality of p-type regions formed in the active region; and a plurality of electrodes formed on the n-type regions and p-type regions formed in the active region. The active region is germanium and the substrate is a different semiconductor material

The active region may be more than 0.4 μm and less than 1 μm, and the electrodes may comprise indium tin oxide, indium zinc oxide, aluminum, doped polycrystalline silicon, or polycrystalline silicon germanium.

It is noted that via-holes may be formed through the passivation layer to the electrodes, the via-holes being filled with metal as appropriate for an integrated circuit fabrication process and being connected to additional metal pads or wires for external interface or connection to other integrated circuit elements fabricated on the substrate.

It is further noted the passivation layer may be silicon dioxide or silicon oxinitride with a thickness of more than 100 nm. An antireflection layer may be formed on the active region and the electrodes, the antireflection layer being silicon dioxide or silicon oxinitride and having a thickness more than 100 nm. Moreover, it is noted that via-holes may be formed through the antireflection layer to the electrodes, the via-holes being filled with metal as appropriate for an integrated circuit fabrication process and being connected to additional metal pads or wires for external interface or connection to other integrated circuit elements fabricated on the substrate.

It is noted that the thickness of the electrodes may be less than 1 μm and the distance between the electrodes formed on the n-type and the electrodes formed on the p-type is more than 0.5 μm and less than 10 μm.

It is also noted that in the various embodiments described above, the type of the region for absorbing the photons was germanium. However, it is noted that a silicon-germanium alloy could also be utilized with similar processing techniques as described.

While various examples and embodiments of the present invention have been shown and described, it will be appreciated by those skilled in the art that the spirit and scope of the present invention are not limited to the specific description and drawings herein, but extend to various modifications and changes.

What is claimed is:

1. A photodetector, comprising:
a substrate, said substrate being a semiconductor material;
an active region formed directly on said substrate, said active region being germanium;
a plurality of n-type doped regions formed in said active region;
a plurality of p-type doped regions formed in said active region;
a plurality of electrodes formed on said n-type doped regions formed in said active region; and
a plurality of electrodes formed on said p-type doped regions formed in said active region.

2. The photodetector as claimed in claim 1, wherein said plurality of n-type doped regions and said plurality of p-type doped regions form an alternating pattern.

3. The photodetector as claimed in claim 1, wherein said electrodes are substantially transparent.

4. The photodetector as claimed in claim 1, wherein said electrodes comprise polycrystalline silicon.

5. The photodetector as claimed in claim 1, wherein said electrodes comprise indium tin oxide, indium zinc oxide, doped polycrystalline silicon or polycrystalline silicon germanium.

6. The photodetector as claimed in claim 1, wherein the thickness of said active region is more than 0.4 μm and less than 1 μm.

7. The photodetector as claimed in claim 1, further comprising:
a passivation layer formed on said active region.

8. The photodetector as claimed in claim 7, wherein said passivation layer is silicon dioxide or silicon oxinitride, the silicon oxinitride having a nitrogen concentration of 0% to 30%.

9. A photodetector as claimed in claim 8, wherein via-holes are formed through said passivation layer to said electrodes, said via-holes are filled with metal as appropriate for an integrated circuit fabrication process, and said filled via-holes are connected to additional metal pads or wires for external interface or connection to other integrated circuit elements fabricated on the said substrate.

10. The photodetector as claimed in claim 7, wherein said passivation layer is more than 100 nm thick.

11. The photodetector as claimed in claim 1, further comprising:
an antireflection layer formed on said active region, said electrodes.

12. The photodetector as claimed in claim 11, wherein said antireflection layer is silicon dioxide or silicon oxinitride.

13. The photodetector as claimed in claim 11, wherein said antireflection layer is more than 100 nm thick.

14. The photodetector as claimed in claim 1, wherein the thickness of said electrodes is less than 1 μm.

15. The photodetector as claimed in claim 1, wherein the distance between said electrodes formed on said n-type regions and said electrodes formed on said p-type regions is more than 0.5 μm and less than 3 μm.

16. The photodetector as claimed in claim 1, wherein the substrate is silicon.

17. The photodetector as claimed in claim 1, wherein the said doped regions are formed by ion implantation through the stated electrodes.

18. The photodetector as claimed in claim 1, wherein the said electrodes are partly or completely covered by an additional electrically conducting material.

19. The photodetector as claimed in claim 18, wherein the said addition conducting material is a metal or combination of metal films typically employed in a standard CMOS process.

20. The photodetector as claimed in claim 4, wherein the said polycrystalline silicon electrodes are formed by deposition followed by ion implantation.

21. The photodetector as claimed in claim 1, wherein the said germanium region is deposited by UHVCVD or LPCVD.

22. The photodetector as claimed in claim 21, wherein the germanium epilayer growth comprises a two-step growth method.

23. The photodetector as claimed in claim 22, wherein the first growth step is carried out at a temperature of approximately 360° C.

24. The photodetector as claimed in claim 22, wherein the second growth step is carried out at a temperature of approximately 700° C. to 750° C.

25. The photodetector as claimed in claim 21, wherein the said germanium region is annealed after growth at approximately 850° C.
